(19) United States
(12) Patent Application Publication
(10) Pub. No.: US 2025/0120293 A1
(43) Pub. Date: Apr. 10, 2025

(54) DISPLAY APPARATUS AND DISPLAY PANEL CONTROLLING VIEWING ANGLE

(71) Applicant: LG Display Co., Ltd., Seoul (KR)

(72) Inventors: SangMoo SONG, Paju-si (KR); Wooseok CHO, Paju-si (KR); Jungseop YOON, Paju-si (KR)

(73) Assignee: LG Display Co., Ltd., Seoul (KR)

(21) Appl. No.: 18/903,290

(22) Filed: Oct. 1, 2024

(30) Foreign Application Priority Data
Oct. 10, 2023 (KR) 10-2023-0134634

(51) Int. Cl. H10K 59/80; H10K 59/40

(52) U.S. Cl. CPC H10K 59/879; H10K 59/8791; H10K 59/40

(57) ABSTRACT

A display device may include a display area having a plurality of pixel sets, and a non-display area disposed adjacent to the display area. At least one of the plurality of pixel sets may include a first pixel controlling a first viewing angle to a first range, a second pixel controlling a second viewing angle to a second range, and a third pixel controlling a third viewing angle to a third range symmetrical to the first range. Each of the first pixel, the second pixel, and the third pixel may include a respective driving transistor, a respective light emitting device, and at least one light control device disposed on the respective light emitting device. The at least one light control device of the third pixel may have a shape symmetrical to the at least one light control device of the first pixel.

### CROSS-REFERENCE TO RELATED APPLICATIONS

This application claims the benefit of and priority to the Korean Patent Application No. 10-2023-0134634 filed on Oct. 10, 2023, the entire contents of which are incorporated herein by reference for all purposes.

### BACKGROUND

### 1. Technical Field

The present disclosure relates to a display apparatus, and particularly to, for example, without limitation, a display panel, and a display panel that controls the viewing angle and a display device including the display panel.

### 2. Description of the Related Art

As the information society develops, various types of display devices have been developed. Recently, various display devices such as a liquid crystal display (LCD), a plasma display panel (PDP), and an organic light emitting display (OLED) have been used.

For reasons such as privacy and information protection, a limitation of a viewing angle of the display device has recently been required. For example, in the case of the display device used as an information medium inside a vehicle, a high-definition image is provided to a passenger in the passenger seat, but a viewing angle needs to be limited to the driver for safety in driving.

The description of the related art should not be assumed to be prior art merely because it is mentioned in or associated with this section. The description of the related art includes information that describes one or more aspects of the subject technology, and the description in this section does not limit the invention.

### SUMMARY

The present disclosure has been made in view of the problems and needs of the related art, including the above problems. In one or more aspects, an object of the present disclosure is to provide a display panel and a display device that can effectively limit a viewing angle.

However, the problems of the present disclosure are not limited to the above-mentioned problems, and other technical problems may be inferred from the following embodiments.

In accordance with an aspect of the present disclosure, the above and other objects can be accomplished by the provision of a display panel and a display device comprising a display area including a plurality of pixel sets, and a non-display area disposed adjacent to the display area, wherein at least one of the plurality of pixel sets includes a first pixel for controlling a first viewing angle to a first range, a second pixel for controlling a second viewing angle to a second range, and a third pixel for controlling a third viewing angle to a third range symmetrical to the first range, the first pixel includes a first driving transistor, a first light emitting device, and at least one first light control device disposed on the first light emitting device, the second pixel includes a second driving transistor, a second light emitting device, and at least one second light control device disposed on the second light emitting device, and the third pixel includes a third driving transistor, a third light emitting device, and at least one third light control device disposed on the third light emitting device, the at least one third light control device having a shape symmetrical to a shape of the first light control device.

Specific matters of other embodiments are included in the detailed description and drawings.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure.

FIG. 1 illustrates an example of a display device according to an example embodiment of the present disclosure.

FIG. 2 illustrates a functional block diagram of a display device according to an example embodiment of the present disclosure.

FIG. 3 illustrates an example of a pixel circuit of a display device according to an example embodiment of the present disclosure.

FIG. 4 is a diagram illustrating an implementation example of a display device according to an example embodiment of the present disclosure.

FIG. 5 illustrates an example of a pixel set according to an example embodiment of the present disclosure.

FIG. 6 shows an example of a cross-section A-A′ of FIG. 5.

FIG. 7 illustrates an example of a cross-section B-B′ of FIG. 5.

FIG. 8 shows an example of a cross-section C-C′ of FIG. 5.

FIG. 9 illustrates an example of a pixel set according to another example embodiment of the present disclosure.

FIG. 10 illustrates an example of a cross-section D-D′ of FIG. 9.

FIG. 11 illustrates an example of a cross-section E-E′ of FIG. 9.

FIG. 12 shows an example of a cross-section F-F′ of FIG. 9.

FIGS. 13A and 13B illustrate examples of a pixel set according to another example embodiment of the present disclosure.

FIG. 14 illustrates an example of a cross-section G-G′ of FIG. 13B.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

The terms used in the embodiments of the present disclosure have been selected as general terms that are currently widely used as possible in consideration of the functions of the present disclosure, but this may vary depending on the intention or precedent of a technician engaged in the field, the emergence of a new technology, and the like. In certain cases, there are terms arbitrarily selected by the applicant, and in this case, the meaning will be described in detail in the applicable description. Therefore, the terms used in this specification should be defined based on the meaning of the term and the overall content of this disclosure, not just the name of the term.

When a part of the specification “includes” a component, it means that it may further include other components rather than excluding them unless otherwise stated.

The expression “at least one of a, b, and c” described throughout the specification may include “a alone”, “b alone”, “c alone”, “a and b”, “a and c”, “b and c”, or “a, b, and c”, or “a, b, and c all”. The advantages and features of the present invention, and methods of achieving them, will become apparent with reference to embodiments described in detail with reference to the accompanying drawings.

Since the shapes, areas, ratios, angles, numbers, etc. disclosed in the drawings for describing embodiments in the present disclosure are illustrative, the embodiments of the present disclosure are not limited to the illustrative matters. In describing embodiments, if it is determined that the detailed description of related known techniques may unnecessarily obscure the gist of embodiments, the detailed description thereof will be omitted.

If “including”, “having”, “being achieved”, or the like mentioned in the present disclosure are used, other parts may be added. In the case of expressing a component in singular, it includes the case of including a plurality unless otherwise explicitly stated. In addition, in interpreting a component, it is interpreted that the error range is included even if there is no separate explicit description.

In the case of a description of the positional relationship, for example, if the positional relationship of two parts is described as “on”, “over”, “below”, “on the side”, etc., one or more other parts may be located between the two parts. What an element or layer is referred to as “on another element” or “on a layer” includes all cases where another layer or another element is interposed just above or in the middle of the other element.

In addition, terms such as first, second, 1-1th, 1-2th, 2-1th, 2-2th, and the like are used to describe various components, but these components are not limited by these terms. These terms are only used to distinguish one component from another component. Thus, the first component mentioned below may be the second component within the technical idea of the present invention

Features of each of the various embodiments of the present disclosure may be partially or entirely combined or combined with each other, may be technically interlocked and driven in various ways, and each embodiment may be performed independently of each other or may be performed together in a related relationship.

In addition, the terms described later are defined in consideration of the functions in the implementation of this specification, and may vary depending on the intention or custom of the user or operator. Therefore, the definition should be made based on the content throughout this specification.

The transistor constituting the pixel circuit of the present disclosure may include at least one of an oxide thin film transistor (TFT), an amorphous silicon TFT (a-Si TFT), and a low temperature polysilicon (LTPS) TFT.

Hereinafter, embodiments will be described focusing on an organic light emitting display device. However, embodiments of the present disclosure are not limited to an organic light emitting display device, and may be applied to an inorganic light emitting display device including an inorganic light emitting material. For example, embodiments of the present disclosure may be applied to a quantum dot display device.

Hereinafter, example embodiments of the present disclosure will be described with reference to the drawings.

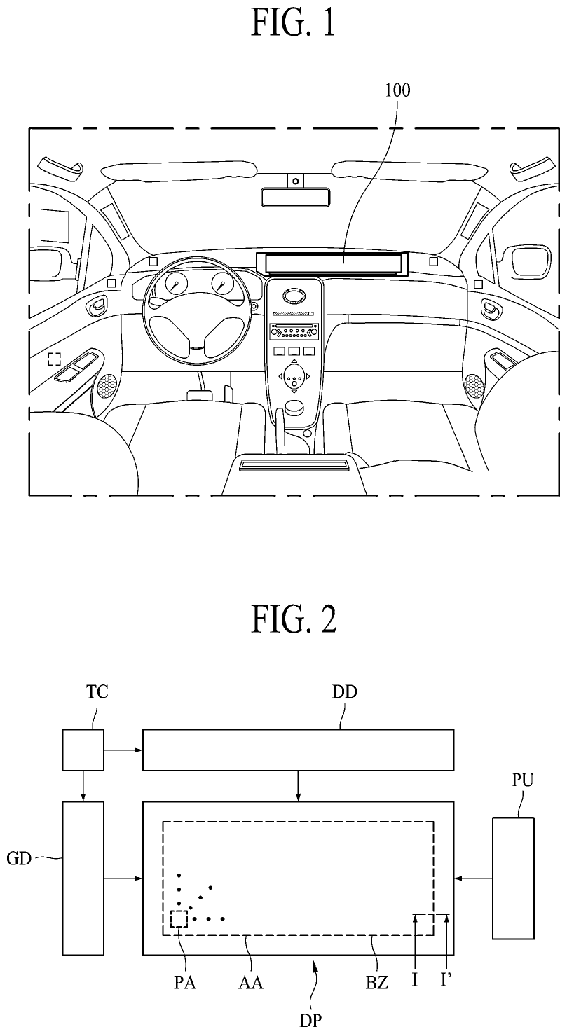

FIG. 1 illustrates an example of a display device according to an example embodiment of the present disclosure.

In an example embodiment, a display device 100 may be disposed on at least a part of a dash board of a vehicle. The display device 100 may be disposed to cross a driver's seat and a passenger seat disposed in a front seat of the vehicle, and may be disposed in front of the front seat. In this case, a user of the display device 100 may include a driver in the driver's seat and a passenger in the passenger seat. That is, both the driver and the passenger of the vehicle may use the display device 100.

Also, the dashboard or the display device 100 may further include an input configuration for manipulating various functions related to an interior of the vehicle. For example, the dashboard or the display device 100 may manipulate an air conditioner, an audio system, a navigation system, and the like.

The display device 100 may provide a variety of information related to the vehicle. For example, the display device 100 may provide vehicle driving information such as a current speed of the vehicle, a remaining fuel amount, and a driving distance. Also, the display device 100 may provide information on vehicle components such as a degree of damage to a vehicle tire.

In an example embodiment, FIG. 1 may illustrate only a part of the display device 100. That is, the display device 100 illustrated in FIG. 1 may indicate a part corresponding to the display panel among various components included in the display device 100. For example, the display device 100 illustrated in FIG. 1 may represent at least a part of a display area and a non-display area of the display panel. In addition, among the components of the display device 100, components other than those illustrated in FIG. 1 may be mounted inside the vehicle.

FIG. 2 is a functional block diagram of a display device according to an example embodiment of the present disclosure.

Referring to FIG. 2, the display device may include a display panel DP, a data driver DD, a gate driver GD, a timing controller TC, and a power supply unit PU.

In an example embodiment, the display panel DP may generate an image to be provided to a user. For example, the display panel DP may generate and display the image to be provided to the user through a pixel area PA in which a pixel circuit is disposed.

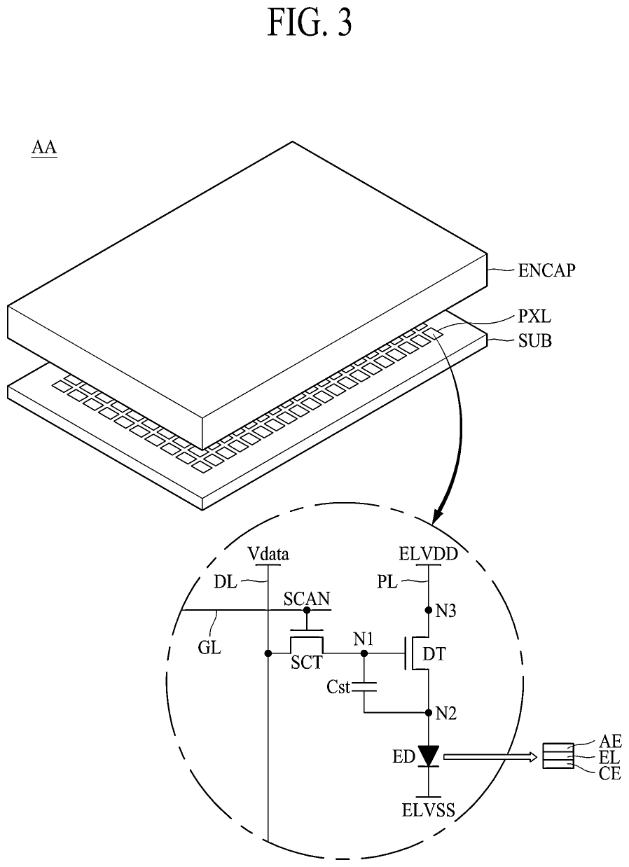

The data driver DD, the gate driver GD, the timing controller TC, and the power supply unit PU may provide a signal for an operation of each pixel area PA through signal lines. The signal lines may include, for example, data lines DL, gate lines GL, and power voltage supply lines PL illustrated in FIG. 3.

For example, the data driver DD may apply a data signal to each pixel area PA through the data lines DL of FIG. 3, the gate driver GD may apply a gate signal to each pixel area PA through the gate lines GL, and the power supply unit PU may supply a power voltage to each pixel area PA through the power voltage supply lines PL.

The timing controller TC may control the data driver DD and the gate driver GD. For example, the timing controller TC may rearrange a digital video data input from an outside to match a resolution of the display panel DP and supply the digital video data to the data driver DD.

The data driver DD may convert the digital video data input from the timing controller TC into an analog data voltage based on a data control signal and supply the analog data voltage to the data lines.

The gate driver GD may generate a scan signal and a light emitting signal based on a gate control signal. The gate driver GD may include a scan driver and a light emitting signal driver. The scan driver may generate a scan signal in a row sequential manner to drive at least one scan line connected to each row of the pixel and supply the scan signal to the scan lines. The light emitting signal driver may generate the light emitting signal in the row sequential manner to drive at least one light emitting signal line connected to each row of the pixel and supply the light emitting signal to the light emitting signal lines.

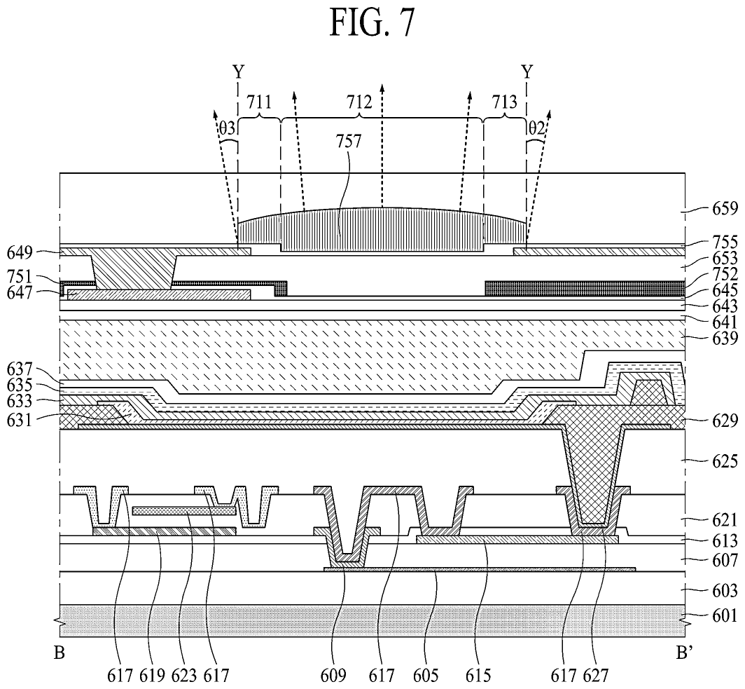

The gate driver GD may generate the plurality of scan signals and the plurality of light emitting signals. For example, the gate driver GD may generate a first scan signal (e.g., the first scan signal Scan(N) of FIG. 7), a second scan signal (e.g., the second scan signal Scan(N−1) of FIG. 7), and the light emitting signal (e.g., the light emitting signal EM(N) of FIG. 7).

According to an example embodiment, the gate driver GD may be disposed on the display panel DP in a gate-driver in-panel (GIP) scheme. For example, the plurality of gate drivers GD may be divided and disposed on at least two side surfaces of the display panel DP, respectively.

The display area AA of the display panel DP may include a plurality of pixel areas (or pixels or pixel circuits) PA. The pixel area PA may include a plurality of data lines (e.g., the data line DL of FIG. 3) and a plurality of gate lines (e.g., the gate line GL of FIG. 3) crossing each other, and a plurality of sub-pixels disposed in each the crossing area. Each of the sub-pixels included in one pixel area PA may emit light of a different color. For example, the pixel area PA may implement blue, red, and green using three sub-pixels. However, the present invention is not limited thereto, and in some cases, the pixel area PA may further include a sub-pixel for further implementing a specific color (e.g., white).

In the pixel area PA, an area implementing blue may be referred to as a blue sub-pixel area, an area implementing red may be referred to as a red sub-pixel area, and an area implementing green may be referred to as a green sub-pixel area.

A non-display area BZ may be disposed along the circumference of the display area AA. Various components for driving a pixel circuit disposed in the pixel area PA may be disposed in the non-display area BZ. For example, at least a portion of the gate driving circuit GD may be disposed in the non-display area BZ. The non-display area BZ may be referred to as a bezel area.

FIG. 3 illustrates an example of a pixel circuit of a display device according to an example embodiment of the present disclosure.

Referring to FIG. 3, in the display area AA, a display panel 10 includes a substrate SUB including sub-pixels PXL and an encapsulation layer ENCAP disposed on the substrate SUB. Each of the sub-pixels PXL includes a light emitting device ED, a driving transistor DT for driving the light emitting device ED, a scan transistor SCT for transferring a data voltage Vdata to the first node N1 of the driving transistor DT, a storage capacitor Cst for maintaining a constant voltage during one frame, and the like.

The driving transistor DT may include a first node N1 to which a data voltage Vdata is applied, a second node N2 electrically connected to the light emitting device ED, and a third node N3 to which a high potential common voltage ELVDD is applied from the driving voltage line PL. In the driving transistor DT, the first node N1 may be a gate node, the second node N2 may be a source node or a drain node, and the third node N3 may be the drain node or the source node.

The light emitting device ED may include an anode AE, a light emitting layer EL, and a cathode CE. The anode AE may be a pixel electrode disposed in each sub-pixel PXL, and may be electrically connected to the second node N2 of the driving transistor DT of each sub-pixel PXL. The cathode CE may be a common electrode disposed in common in the plurality of sub-pixels PXL, and a low potential voltage ELVSS may be applied thereto.

For example, the anode AE may be the pixel electrode, and the cathode CE may be the common electrode. Conversely, the anode AE may be the common electrode, and the cathode CE may be the pixel electrode. In the following, for convenience of explanation, it is assumed that the anode AE is the pixel electrode and the cathode CE is the common electrode.

For example, the light emitting device ED may be an organic light emitting diode, an inorganic light emitting diode, a quantum dot light emitting device, or the like. When the light emitting device ED is the organic light emitting diode, the light emitting layer EL of the light emitting device ED may include an organic light emitting layer including an organic material.

The on/off of the scan transistor SCT is controlled by the scan signal SCAN, which is the gate signal applied through the gate line GL. The scan transistor SCT may switch an electrical connection between the first node N1 of the driving transistor DT and the data line DL.

The storage capacitor Cst may be electrically connected between the first node N1 and the second node N2 of the driving transistor DT.

According to an example embodiment, each sub-pixel PXL may further include one or more transistors, or may further include one or more capacitors.

Each of the driving transistor DT and the scan transistor SCT may be an n-type transistor or a p-type transistor.

In an example embodiment, at least one of the driving transistor DT and the scan transistor SCT uses an oxide semiconductor layer as an active layer. The oxide semiconductor layer is a layer made of an oxide semiconductor material, and has an excellent leakage current blocking effect and a relatively low manufacturing cost compared to a transistor using a polycrystalline semiconductor layer. For example, the oxide semiconductor layer may include IGZO, ZnO, SnO2, Cu2O, NiO, ITZO, and/or IAZO, and configurations of the present disclosure are not limited thereto.

A polycrystalline semiconductor material, for example, a transistor using a polycrystalline semiconductor layer including poly-Si, has a fast operation speed and excellent reliability. According to an example embodiment, based on the advantages of the polycrystalline semiconductor layer, at least one of the driving transistor DT and the scan transistor SCT may be manufactured using the polycrystalline semiconductor layer.

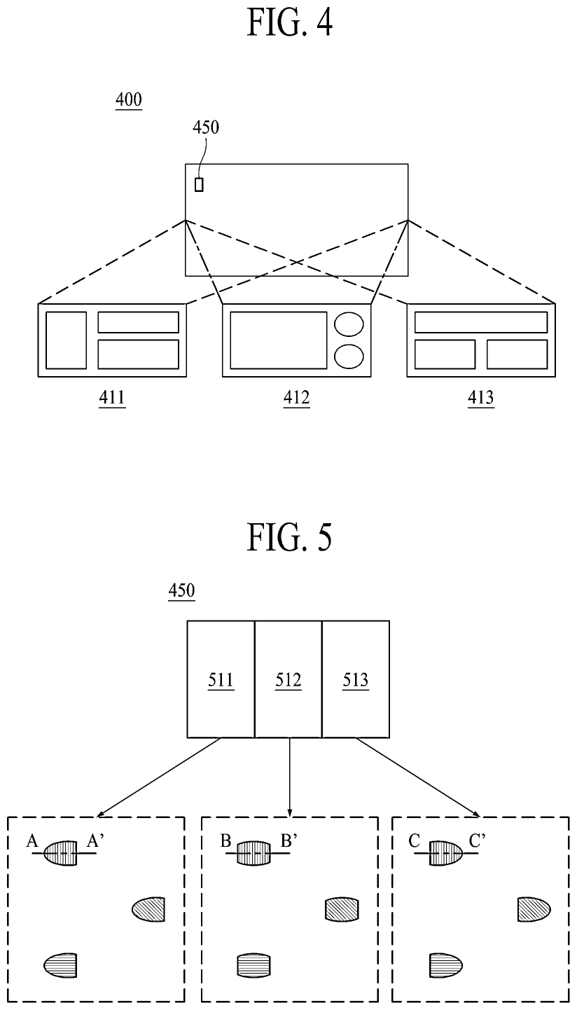

FIG. 4 is a diagram illustrating an implementation example of a display device according to an example embodiment of the present disclosure.

Referring to FIG. 4, a display device 400 may have a plurality of viewing angles. For example, the display device 400 may have a viewing angle of a first range, a viewing angle of a second range, and a viewing angle of a third range. The display device 400 may allow a first screen 411 to be provided in the first range, a second screen 412 to be provided in the second range, and a third screen 413 to be provided in the third range.

In an example embodiment, the first range may include a range corresponding to a driver's seat, and the second range may include a range corresponding to an area between the driver's seat and the passenger's seat, for example, a front range. Also, the third range may include a range corresponding to the passenger's seat.

In an example embodiment, the first screen 411, the second screen 412, and the third screen 413 may display different content. However, the present invention is not limited thereto, and at least two screens may display the same content according to an example embodiment.

The display device 400 may include a plurality of pixel sets. At least one of the plurality of pixel sets may include a first pixel operating to correspond to the viewing angle of the first range, a second pixel operating to correspond to the viewing angle of the second range, and a third pixel operating to correspond to the viewing angle of the third range. Each of the first pixel, the second pixel, and the third pixel may include a plurality of sub-pixels emitting different colors. Hereinafter, a first pixel set 450 including the first pixel, the second pixel, and the third pixel will be described in more detail with reference to FIG. 5.

In an example embodiment, the display device 400 may include a display area including the plurality of pixel sets and a non-display area disposed adjacent to the display area. At least one of the plurality of pixel sets may include the first pixel, the second pixel, and the third pixel.

FIG. 5 illustrates an example of a pixel set according to an example embodiment of the present disclosure. FIG. 5 illustrates pixel arrangement according to an example embodiment of the present disclosure for providing different screens in different ranges as illustrated in FIG. 4.

Referring to FIG. 5, the first pixel set 450 may include a first pixel 511, a second pixel 512, and a third pixel 513. Each pixel may include a plurality of sub-pixels. For example, each pixel may include a plurality of sub-pixels emitting different colors. For example, as illustrated, one first color sub-pixel, one second color sub-pixel, and one third color sub-pixel may be included. Hereinafter, it is assumed that the first color is red, the second color is green, and the third color is blue, but the present invention is not limited thereto.

In an example embodiment, the first pixel 511 may display a first screen 411 by providing light in the first range, for example, the first range of FIG. 4, the second pixel 512 may display a second screen 412 by providing light in the second range, for example, the second range of FIG. 4, and the third pixel 513 may display a third screen 413 by providing light in the third range, for example, the third range of FIG. 4.

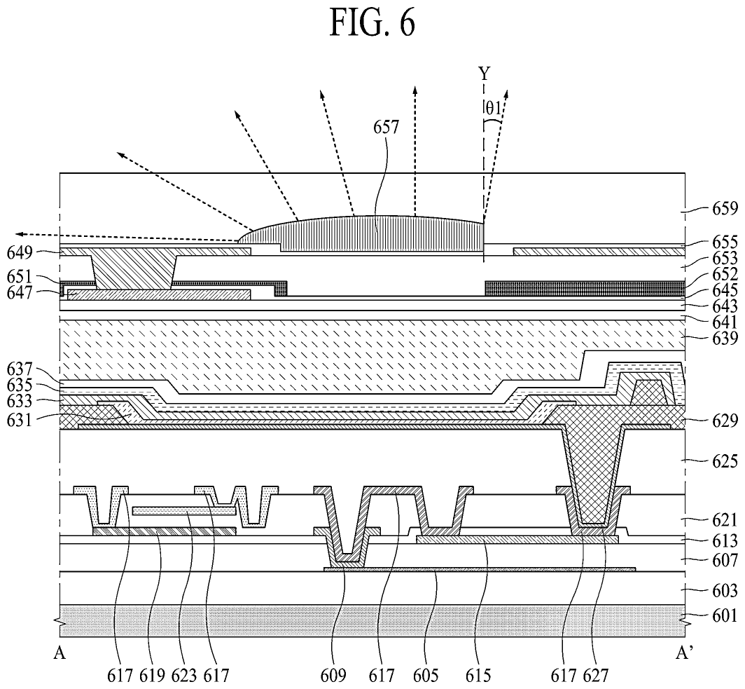

In an example embodiment, the first pixel 511 may include a first driving transistor, a first light emitting device, and at least one first light control device disposed on the first light emitting device. Examples in which the at least one first light control device is disposed on the light emitting device may be referred to in FIGS. 6 to 8. The first pixel 511 may control the viewing angle within the first range.

In an example embodiment, the second pixel 512 may include a second driving transistor, a second light emitting device, and at least one second light control device disposed on the second light emitting device. An example in which the at least one second light control device is disposed on the light emitting device may be referred to in FIGS. 6 to 8. The second pixel 512 may control the viewing angle within the second range.

In an example embodiment, the third pixel 513 may include a third driving transistor, a third light emitting device, and at least one third light control device disposed on the third light emitting device. Examples in which the at least one third light control device is disposed on the light emitting device may be referred to in FIGS. 6 to 8. The third pixel 513 may control the viewing angle within the third range.

In an example embodiment, the light control device for controlling the viewing angle may be disposed on each sub-pixel. The light control device may have different shapes in each of the first pixel 511, the second pixel 512, and the third pixel 513. A more specific example related to this may be confirmed through FIGS. 6 to 8.

Here, the light control device may refer to a tool that refracts light and then collects or spreads the light. The light control device may include, for example, a lens, but is not limited thereto. The light control device may be implemented using the same material as that of a planarization layer 625 of FIG. 6. For example, the light control device may be formed of at least one of acrylic resins, epoxy resins, phenolic resins, polyamide resins, unsaturated polyester resins, polyphenylene resins, polyphenylene sulfides resins, and benzocyclobutene, but is not limited thereto.

FIG. 5 shows an example in which the first pixel 511, the second pixel 512, and the third pixel 513 are sequentially arranged from left to right. However, the present invention is not limited thereto, and positions of the first pixel 511, the second pixel 512, and the third pixel 513 may be variously changed in some cases. For example, the first pixel 511, the third pixel 513, and the second pixel 512 may be sequentially arranged from right to left in that order.

In an example embodiment, cross-sections of the sub-pixels included in each of the first pixel 511, the second pixel 512, and the third pixel 513 may be the same. Hereinafter, on the assumption of such a case, in FIGS. 6 to 8, a cross-section of the first color sub-pixel for each pixel is shown in more detail.

According to an example embodiment, a pixel may be referred to as an area. For example, the first pixel 511 may be referred to as a first area, the second pixel 512 may be referred to as a second area, and the third pixel 513 may be referred to as a third area. The term “pixel” is only a term for distinguishing a light emitting area, and an example embodiment is not limited to this term.

FIG. 6 illustrates an example of a cross-section A-A′ of FIG. 5. FIG. 6 illustrates a cross-section of a sub-pixel emitting a first color.

Referring to FIG. 6, a first buffer layer 603 may be disposed on a substrate 601. The substrate 601 may be composed of at least one layer. The substrate 601 may have a flexible material. For example, the substrate 601 may be a plastic substrate. The first buffer layer 603 may be a multi-buffer including a plurality of layers. A shield metal (or a bottom shield metal (BSM) 605 may be disposed on the first buffer layer 603. An active buffer layer 607 may be disposed on the shield metal 605 and the first buffer layer 603.

The shield metal 605 may be exposed through a contact hole. A connection electrode 609 may be connected to the shield metal 605 through a contact hole. An insulating layer 613 may be disposed on the active buffer layer 607. An active layer 615 may be further disposed on the active buffer layer 607. The active layer 615 may constitute a channel of a transistor. The active layer 615 may be formed of, for example, silicon.

A first insulating layer 613 may include a contact hole exposing at least a portion of the active layer 615. The active layer 615 may be connected to a source/drain electrode 617 through the contact hole. The source/drain electrode 617 may correspond to a metal constituting a source electrode and/or a drain electrode of the transistor.

The connection electrode 609 may be connected to the source/drain electrode 617. In this case, the shield metal 605 may be electrically connected to the source/drain electrode 617 through the connection electrode 609. In an example embodiment, a material forming the connection electrode 609 may correspond to a material forming a gate electrode 619. In this case, the connection electrode 609 may be formed through the same process as the gate electrode 619.

The gate electrode 619 may be disposed on the first insulation layer 613. A second insulation layer 621 may be disposed on the gate electrode 619. The second insulation layer 621 may be disposed on the gate electrode 619, the connection electrode 609, and the first insulation layer 613. The second insulation layer 621 may include a plurality of layers. For example, the second insulation layer 621 may include a 2-1th insulation layer and a 2-2th insulation layer. In this case, a metal layer 623 may be disposed between the 2-1th insulation layer and the 2-2th insulation layer. The metal layer 623 may be disposed to overlap the gate electrode 619. In this case, a capacitor may be formed based on the metal layer 623 and the gate electrode 619.

In an example embodiment, the second insulating layer 621 may include a contact hole exposing at least a portion of the gate electrode 619 and/or the metal layer 623. The source/drain electrode 617 may be connected to the gate electrode 619 and/or the metal layer 623 through a contact hole.

A planarization layer 625 may be disposed on the source/drain electrode 617 and the second insulating layer 621. The planarization layer 625 may include a contact hole. The contact hole of the planarization layer 625 may expose at least a portion of the source/drain electrode. An anode 627 of the light emitting device may be disposed on the planarization layer 625. The anode 627 may also be disposed in the contact hole of the planarization layer 625. In this case, the anode 627 may be connected to the source/drain electrode 617 through the contact hole. A bank 629 may be disposed on at least a portion of the anode 627 and at least a portion of the planarization layer 625. The bank 629 may be disposed between the light emitting devices to partition the pixels.

In an example embodiment, the gate electrode 619, the source/drain electrode 617, and the active layer 615 may constitute a driving transistor. An anode 627, a light emitting layer 631, and a cathode 633 may be sequentially disposed on the driving transistor.

The light emitting layer 631 and the cathode 633 may be sequentially stacked on the anode 627. An ALD layer 635 may be disposed on the cathode 633. The ALD layer 635 may improve the reliability of the light emitting device. For example, the ALD layer 635 may improve the reliability by preventing gas and/or foreign substances that may be generated at a high temperature from penetrating into at least a part of the light emitting device. An encapsulation layer may be disposed on the ALD layer 635. The encapsulation layer may include a first encapsulation layer 637, a second encapsulation layer 639, and a third encapsulation layer 641. The encapsulation layer may correspond to the encapsulation layer ENCAP of FIG. 3.

In an example embodiment, the encapsulation layer and a buffer layer, for example, a second buffer layer 643 may be sequentially disposed on the cathode 633.

The second buffer layer 643 may be disposed on the encapsulation layer. A touch electrode may be disposed on the second buffer layer 643. For example, a first touch electrode 647 and a first touch protection layer 645 may be disposed on the second buffer layer 643. The first touch protection layer 645 may be disposed to cover at least a portion of the first touch electrode 647. The first touch protection layer 645 may include a contact hole exposing at least a portion of the first touch electrode 647. A second touch electrode 649 may be disposed in the contact hole.

In an example embodiment, the first touch electrode 647 may be a bridge electrode, and the second touch electrode 649 may be a sensor electrode. The second touch electrode 649 may be connected to the first touch electrode 647 by filling the contact hole.

According to an example embodiment, a first barrier layer 651 may be disposed to surround an upper surface and a side surface of the first touch protection layer 645 on the first touch electrode 647. The second barrier layer 652 may be spaced apart from the first barrier layer 651 and may be disposed on the first touch protection layer 645. The first barrier layer 651 and the second barrier layer 652 may be implemented as a black mattress to block light. In this case, light may pass between the first barrier layer 651 and the second barrier layer 652. For example, as the light emitting device, i.e., the anode 627, the light emitting layer 631, and the cathode 633 are disposed below the first barrier layer 651 and the second barrier layer 652, light may be generated. The generated light may be emitted through a space between the first barrier layer 651 and the second barrier layer 652.

According to an example embodiment, at least a portion of the first light control device may be disposed between the first barrier layer 651 and the second barrier layer 652. For example, as illustrated, at least a portion of the first light control device may be disposed to overlap on a region between the first barrier layer 651 and the second barrier layer 652.

In an example embodiment, the first touch planarization layer 653 may be disposed to surround a side surface and a upper portion of the first barrier layer 651 and a side surface and a upper portion of the second barrier layer 652, and portions disposed in the contact hole of the second touch electrode 649. At least a portion of the second touch electrode 649 may be disposed on an upper surface of at least a portion of the first touch planarization layer 653. A second touch protection layer 655 may be disposed on an upper portion of the second touch electrode 649 and the remaining area of the first touch planarization layer 653.

A first light control device 657 may be disposed on the second touch protection layer 655. The first light control device 657 may be disposed between the first barrier layer 651 and the second barrier layer 652. For example, at least a portion of the first light control device 657 may be disposed between the first barrier layer 651 and the second barrier layer 652.

According to an example embodiment, the second barrier layer 652 may cover the other first touch electrode. In this case, the touch electrode on the second barrier layer 652 may also represent a part of the other second touch electrode.

In a plan view, the first light control device 657 may have a shape in which a part of the elliptical shape is cut off. For example, as illustrated in FIG. 5, the first light control device 657 may have a shape in which a part of the right side of the ellipse is cut off, in a plan view. That is, the cross-section of the first light control device 657 may have a semi-elliptical shape.

One side of the first light control device 657 may have a cross-section perpendicular to the substrate 601. Also, an upper surface from one side to the other side of the first light control device 657 may have a curved shape. Also, the first light control device 657 may have a shape that gradually decreases in thickness from one side to the other side of the first light control device 657. In this case, the thickness of one side of the first light control device 657 may be thicker than the thickness of the other side of the first light control device 657.

In this case, an emission angle of light may be controlled corresponding to the shape of the light control device. For example, light may be emitted from one end of the first light control device 657 in the direction of a first angle θ1, and the first angle θ1 may be an angle formed by one end of the first light control device 657 and the central axis Y perpendicular to the substrate 601. In a range exceeding the first angle θ1, the emission of light may be limited.

The first light control device 657 may control light to be emitted in a range of −90° or more and less than the first angle θ1. This light emission range may correspond to a first range. Here, the first angle θ1 may be, for example, +30°, but is not limited thereto, and may have a specific value corresponding to a range of, for example, 0° or more and less than +35°.

That is, referring to FIG. 6, a range of an angle of light emitted from one side of the first light control device 657 may be smaller than a range of an angle of light emitted from the other side of the first light control device 657. Accordingly, the user cannot visually recognize light from one direction of the first light control device 657, and may visually recognize light only from the other direction of the first light control device 657.

A second touch planarization layer 659 may be disposed to cover the first light control device 657 and the second touch protection layer 655. Although not illustrated, an adhesive layer, a polarization layer, and a cover glass may be further disposed on the second touch planarization layer 659. For example, the adhesive layer, the polarization layer, and the cover glass may be sequentially disposed on the second touch planarization layer 659.

In some cases, a back plate and/or an aluminum plate may be further disposed below the substrate 601. For example, the back plate may be disposed on an aluminum plate, and the substrate 601 may be disposed on the back plate. The aluminum plate may serve to support the substrate 601 and the back plate and dissipate heat from the substrate 601 and the back plate. The back plate may serve to support the substrate 601.

FIG. 7 illustrates an example of a cross-section taken along line B-B′ of FIG. 5. FIG. 7 illustrates a cross-section when a light control device of a different type from the first light control device 657 of FIG. 6 is disposed on the light emitting device. In this case, the light control device of the different type from the first light control device 657 may be the second light control device 757. The light emitting device of FIG. 7 emits a first color.

Referring to FIG. 7, the second light control device 757 may be disposed on the touch protection layer 755. The second light control device 757 may be disposed to overlap a region between the first barrier layer 751 and the second barrier layer 752. For example, at least a portion of the second light control device 757 may be disposed between the first barrier layer 751 and the second barrier layer 752. A first region 711 of the second light control device 757 may be disposed to overlap the first barrier layer 751, and a second region 712 of the second light control device 757 may be disposed to overlap a region between the first barrier layer 751 and the second barrier layer 752. A third region 713 of the second light control device 757 may be disposed to overlap the second barrier layer 752.

In an example embodiment, at least a portion of the first region 711 and the third region 713 may also overlap the touch electrode. In this case, the second light control device 757 may be provided to sufficiently cover a region between the first barrier layer 751 and the second barrier layer 752, so that all light emitted through the light emitting device at a lower end may be controlled through the second light control device 757.

In a plan view, the second light control device 757 may have a shape in which both sides of an ellipse are cut off. For example, the second light control device 757 may have a shape in which both sides of a convex lens are vertically cut off. As another example, both sides of the second light control device 757 may have a first height, but a height of the second light control device 757 increases as it approaches the center. That is, an end of the first region 711 and an end of the third region 713 may have cross-sections perpendicular to the substrate 601. Also, the second region 712 may have a curved shape.

The light passing through the second light control device 757 may be emitted head-on. For example, light passing through the second light control device 757 may be controlled not to be emitted to a part of a left side and a right side of the light control device. For another example, the light passing through the second light control device 757 may be controlled to be emitted within a range greater than or equal to the-third angle θ3 and less than or equal to the second angle θ2 based on the central axis Y of the second light control device 757. For example, when the second angle θ2 is 30° and the third angle θ3 is 20°, the light may be emitted in the range of −20° or more and +30° or less. In some cases, the second angle θ2 or the third angle θ3 may have a specific value corresponding to a range greater than or equal to 0° and less than or equal to +35°.

In some cases, the second angle θ2 and the third angle θ3 may have the same value. For example, both the second angle θ2 and the third angle θ3 may be 30°. In this case, light may be emitted in the range of +30° or less and −30° or more. The range in which such light is emitted may be referred to as the second range.

That is, referring to FIG. 7, the user cannot visually recognize light in both end directions of the second light control device 757, and may visually recognize light only in the front direction of the second light control device 757.

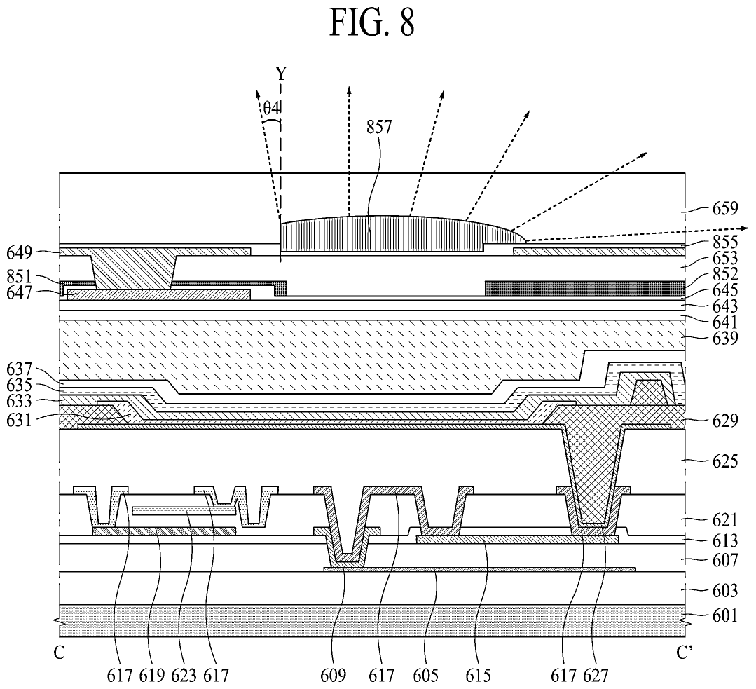

FIG. 8 illustrates an example of a cross-section C-C′ of FIG. 5. FIG. 8 illustrates a cross-section when a light control device of a type different from that of the first light control device 657 of FIG. 6 is disposed on a light emitting device. The light control device may be a third light control device 857. The light emitting device of FIG. 8 emits a first color.

Referring to FIG. 8, a third light control device 857 may be disposed on the touch protection layer 875. The third light control device 857 may be disposed to overlap a region between the first barrier layer 851 and the second barrier layer 852. For example, at least a portion of the third light control device 857 may be disposed between the first barrier layer 851 and the second barrier layer 852. A first region of the third light control device 857 may be disposed to overlap the second barrier layer 852, and a second region of the third light control device 857 may be disposed to overlap the region between the first barrier layer 851 and the second barrier layer 852.

In a plan view, the third light control device 857 may have a shape in which a part of the elliptical shape is cut off. For example, the third light control device 857 may have a shape in which a part of the left side of the ellipse is cut off, in a plan view. That is, the cross-section of the third light control device 857 may have a semi-elliptical shape. Also, the third light control device 857 may have a shape symmetrical with first light control device 657, in a plan view.

One side of the third light control device 857 may have a cross-section perpendicular to the substrate 601. Also, an upper surface from one side to the other side of the third light control device 857 may have a curved shape. Also, the third light control device 857 may have a shape that gradually decreases in thickness from one side to the other end of the third light control device 857. In this case, a thickness of one side of the third light control device 857 may be thicker than a thickness of the other side of the third light control device 857.

In this case, an emission angle of light may be controlled corresponding to the shape of the light control device. For example, light may be emitted from one end of the third light control device 857 in the direction of a fourth angle −θ4, and the fourth angle θ4 may be an angle formed by one end of the third light control device 857 and the central axis Y perpendicular to the substrate 601. In a range exceeding the fourth angle −θ4, the emission of light may be limited.

The third light control device 857 may control light to be emitted in a range of the fourth angle −θ4 or more and less than 90°. This light emission range may correspond to a third range. Here, the fourth angle θ4 may be, for example, +30°, but is not limited thereto, and may have a specific value corresponding to a range of, for example, 0° or more and less than +35°.

That is, referring to FIG. 8, a range of an angle of light emitted from one side of the third light control device 857 may be smaller than a range of an angle of light emitted from the other side of the third light control device 857. Accordingly, the user cannot visually recognize light from one direction of the third light control device 857, and may visually recognize light only from the other direction of the third light control device 857.

In an example embodiment, + of the light emission angle may mean that light is emitted in the first direction, and − of the light emission angle may mean that light is emitted in a second direction opposite to the first direction.

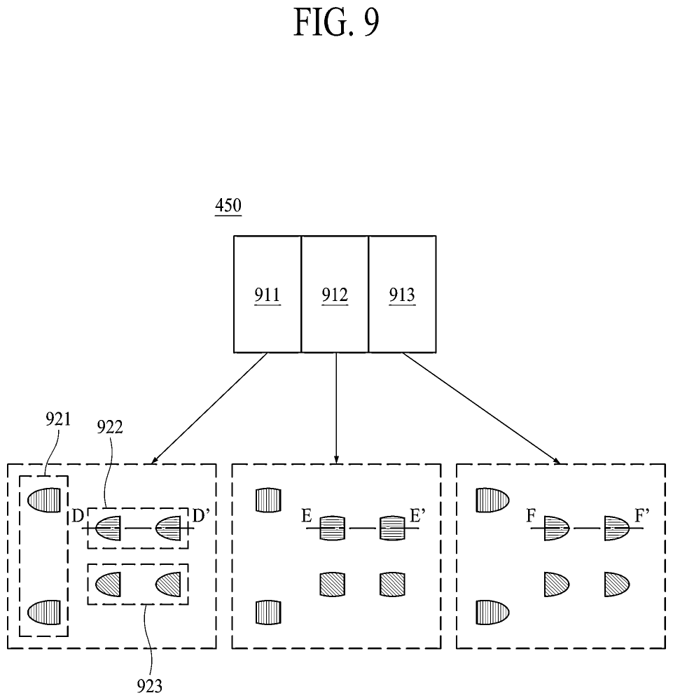

FIG. 9 illustrates an example of a pixel set according to another example embodiment of the present disclosure. FIG. 9 illustrates a case in which one sub-pixel includes a plurality of light control devices.

Referring to FIG. 9, a first pixel set 450 may include a first pixel 911, a second pixel 912, and a third pixel 913. Each pixel may include a plurality of sub-pixels. For example, each pixel may include a plurality of sub-pixels emitting different colors. For example, as illustrated, one first color sub-pixel 921, one second color sub-pixel 922, and one third color sub-pixel 923 may be included. Hereinafter, it is assumed that the first color is red, the second color is green, and the third color is blue, but the present invention is not limited thereto.

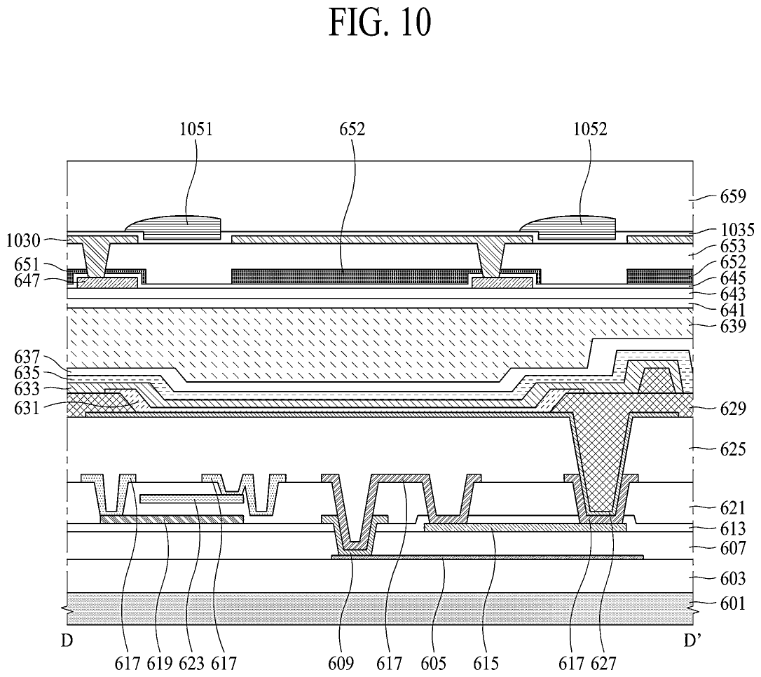

In an example embodiment, a plurality of light control devices may be disposed on each sub-pixel. The light control device may be disposed in various ways. For example, the light control device may be vertically disposed like the first color sub-pixel 921. For another example, the light control device may be disposed horizontally like the second color sub-pixel 922 and/or the third color sub-pixel 923. Hereinafter, in FIGS. 10 to 12, one or more examples of a cross-section of the second color sub-pixel 922 will be described.

FIG. 10 illustrates an example of a cross-section D-D′ of FIG. 9. FIG. 9 illustrates a cross-section when a plurality of first light control devices are disposed on a light emitting device emitting a second color. Hereinafter, the same contents as those described with reference to FIGS. 6 to 9 may be omitted.

Referring to FIG. 10, a plurality of light control devices may be disposed on the light emitting device emitting the second color. For example, a 1-1th light control device 1051 and a 1-2th light control device 1052 may be disposed on the light emitting device. Here, the 1-1th light control device 1051 and the 1-2th light control device 1052 may be the same type of light control device as the first light control device 657 of FIG. 6. For example, the 1-1 light control device 1051 and the 1-2th light control device 1052 may be configured to control light to be emitted in the first range.

In an example embodiment, the 1-1th light control device 1051 may be spaced apart from the 1-2th light control device 1052 by a predetermined distance. At least a portion of the touch electrode 1030 may be disposed between the 1-1th light control device 1051 and the 1-2th light control device 1052. A touch protection layer 1035 may be disposed on the touch electrode 1030.

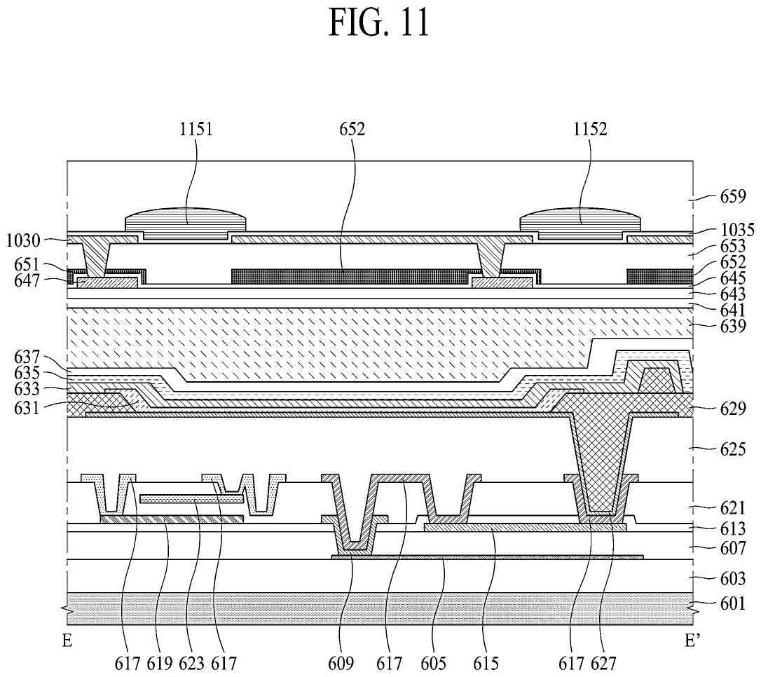

FIG. 11 illustrates an example of a cross-section E-E′ of FIG. 9. FIG. 11 illustrates a cross-section when a plurality of second light control devices are disposed on a light emitting device emitting a second color.

Referring to FIG. 11, a plurality of light control devices may be disposed on a light emitting device emitting the second color. For example, a 2-1th light control device 1151 and a 2-2th light control device 1152 may be disposed on the light emitting device. Here, the 2-1th light control device 1151 and the 2-2th light control device 1152 may be the same type of light control device as the second light control device 757 of FIG. 7. For example, the 2-1th light control device 1151 and the 2-2th light control device 1152 may be configured to control light to be emitted in the second range. The 2-1th light control device 1151 may be spaced apart from the 2-2th light control device 1152 by a predetermined distance, and may be disposed on the light emitting device.

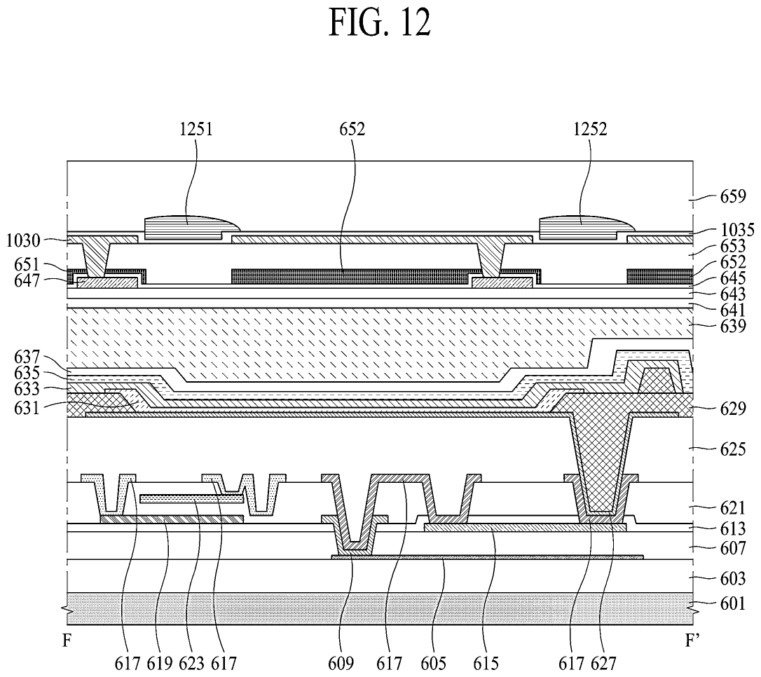

FIG. 12 illustrates an example of a cross-section F-F′ of FIG. 9. FIG. 12 illustrates a cross-section when a plurality of third light control devices are disposed on a light emitting device emitting the second color.

Referring to FIG. 12, a plurality of light control devices may be disposed on a light emitting device emitting the second color. For example, the 3-1th light control device 1251 and the 3-2th light control device 1252 may be disposed on the light emitting device. Here, the 3-1th light control device 1251 and the 3-2th light control device 1252 may be the same type of light control device as the third light control device 857 of FIG. 8. For example, the 3-1th light control device 1251 and the 3-2th light control device 1252 may be configured to control light to be emitted in the third range. The 3-1th light control device 1251 and the 3-2th light control device 1252 may be spaced apart from each other by a predetermined distance and may be disposed on the light emitting device.

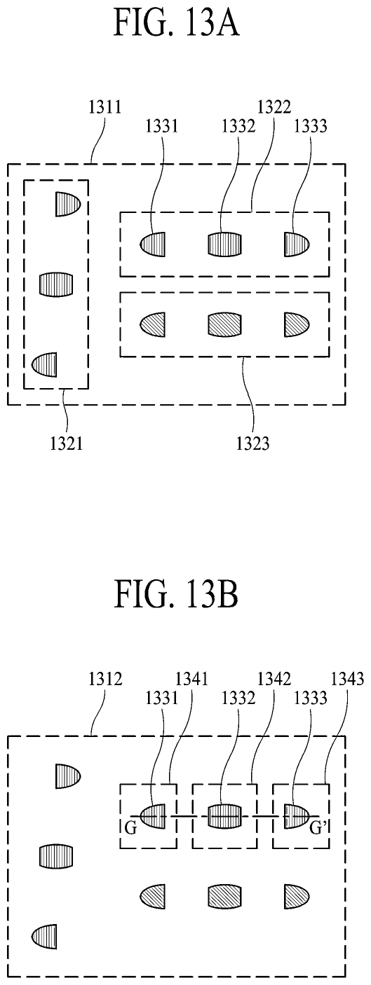

FIGS. 13A and 13B illustrate examples of a pixel set according to another example embodiment of the present disclosure.

Referring to FIG. 13A, sub-pixels emitting light of different colors may be disposed in a first pixel set 1311. One sub-pixel in the first pixel set 1311 may be disposed for each light emitting color, and the sub-pixel may include several types of lenses. For example, the first pixel set 1311 may include a first sub-pixel 1321 including a first light emitting device emitting a first color, a second sub-pixel 1322 including a second light emitting device emitting a second color, and a third sub-pixel 1323 including a third light emitting device emitting a third color.

Light control devices having different light emission ranges may be disposed in each sub-pixel. For example, the second sub-pixel 1322 may include a first light control device 1331 that emits light in a first range, a second light control device 1332 that emits light in a second range, and a third light control device 1333 that emits light in a third range. In this case, the first light control device 1331, the second light control device 1332, and the third light control device 1333 may be disposed on one light emitting device.

Referring to FIG. 13B, sub-pixels emitting light of different colors may be disposed in the second pixel set 1312. One sub-pixel in the second pixel set 1312 may be disposed for each light control device. For example, if there are three types of light control devices in relation to one color light emission, sub-pixels may be provided for each type of light control device. For example, a 2-1th sub-pixel 1341, a 2-2th sub-pixel 1342, and a 2-3th sub-pixel 1343 may be disposed and emit the second color.

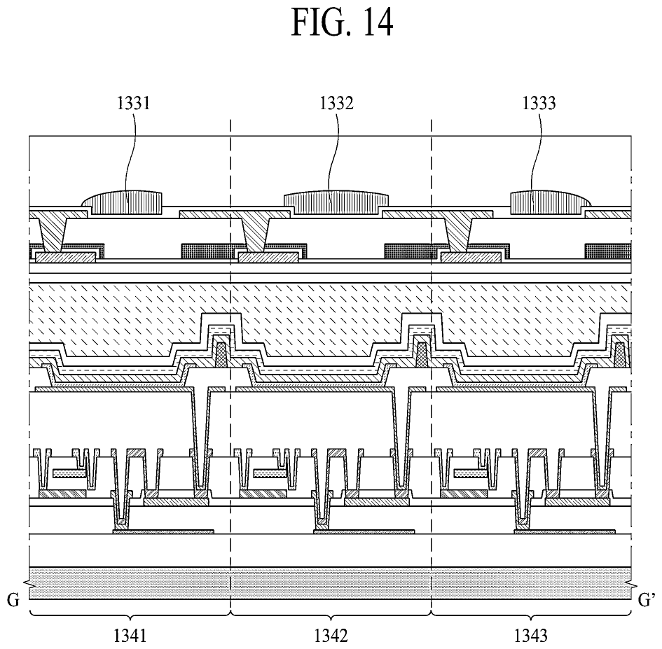

In an example embodiment, different types of lenses may be disposed in the 2-1th sub-pixel 1341, the 2-2th sub-pixel 1342, and the 2-3th sub-pixel 1343. For example, the first light control device 1331 may be disposed in the 2-1th sub-pixel 1341. The second light control device 1332 may be disposed in the 2-2th sub-pixel 1342. The third light control device 1333 may be disposed in the 2-3th sub-pixel 1343. For a more specific example related to this, a cross-section of G-G′ which will be described with reference to FIG. 14 may also be referred to.

According to one or more aspects of the present disclosure, the following advantageous effects may be obtained.

According to one or more aspects of the present disclosure, the plurality of light conversion layers may be formed so that light efficiency may be improved, and reflectance due to external light may be reduced.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display device, comprising:
a substrate;
a display area and a non-display area disposed adjacent to the display area; and
a plurality of pixel sets disposed on the substrate,
wherein:
at least one of the plurality of pixel sets includes a first pixel for controlling a first viewing angle to a first range, a second pixel for controlling a second viewing angle to a second range, and a third pixel for controlling a third viewing angle to a third range;
the first pixel includes a first driving transistor, a first light emitting device, and at least one first light control device disposed on the first light emitting device;
the second pixel includes a second driving transistor, a second light emitting device, and at least one second light control device disposed on the second light emitting device; and
the third pixel includes a third driving transistor, a third light emitting device, and at least one third light control device disposed on the third light emitting device.

2. The display device of claim 1, wherein the first light emitting device comprises an anode, a light emitting layer and a cathode that are sequentially disposed on the first driving transistor, and
an encapsulation layer and a buffer layer are sequentially disposed on the cathode.

3. The display device of claim 2, further comprising:
a touch electrode and a touch protection layer disposed on the buffer layer; and
a barrier layer overlapping the touch electrode, the barrier layer including a black matrix.

4. The display device of claim 3, wherein the touch protection layer is disposed to cover at least a portion of the touch electrode, and
the at least one first light control device is disposed on the touch protection layer.

5. The display device of claim 1, wherein the at least one first light control device and the at least one third light control device have a shape in which one side of an elliptical shape is cut off, in a plan view, and
the at least one second light control device has a shape in which both sides of the elliptical shape are cut off, in a plan view.

6. The display device of claim 5, wherein the shape of the at least one first light control device and the shape of the at least one third light control device are symmetrical to each other in a plan view.

7. The display device of claim 1, wherein a cross-section of one side of the at least one first light control device and a cross-section of one side of the at least one third light control device have a semi-elliptical shape, and
cross-sections of both sides of the at least one second light control device have a semi-elliptical shape.

8. The display device of claim 7, wherein the cross-section of the one side of the at least one first light control device and the cross-section of the one side of the at least one third light control device are perpendicular to the substrate, and
the cross-sections of the both sides of the at least one second light control device are perpendicular to the substrate.

9. The display device of claim 1, wherein the at least one first light control device of the first pixel is a single first light control device.

10. The display device of claim 1, wherein the at least one first light control device of the first pixel comprises two or more first light control devices spaced apart from each other.

11. The display device of claim 1, wherein the first light emitting device, the second light emitting device, and the third light emitting device are configured to emit light of a same color.

12. The display device of claim 1, wherein each of the first pixel, the second pixel, and the third pixel further includes an aluminum plate, a back plate, and a multi-buffer layer, and
the first pixel, the second pixel, and the third pixel have the aluminum plate, the back plate, and the multi-buffer layer in common.

13. The display device of claim 1, wherein
the first range includes a direction of one side of the display area,
the second range includes a center direction of the display area, and
the third range includes a direction of the other side of the display area opposite to the one side.

14. The display device of claim 1, wherein:
the at least one first light control device is configured to control the first viewing angle to the first range;
the at least one second light control device is configured to control the second viewing angle to the second range; and
the at least one third light control device is configured to control the third viewing angle to the third range.

15. A display panel, comprising:
a display area including a plurality of pixel sets; and
a non-display area disposed adjacent to the display area,
wherein:
at least one of the plurality of pixel sets includes a first pixel for controlling a first viewing angle to a first range, a second pixel for controlling a second viewing angle to a second range, and a third pixel for controlling a third viewing angle to a third range symmetrical to the first range;
the first pixel includes a first driving transistor, a first light emitting device, and at least one first light control device disposed on the first light emitting device;
the second pixel includes a second driving transistor, a second light emitting device, and at least one second light control device disposed on the second light emitting device; and
the third pixel includes a third driving transistor, a third light emitting device, and at least one third light control device disposed on the third light emitting device, the at least one third light control device having a shape symmetrical to a shape of the at least one first light control device.
the third pixel includes a third driving transistor, a third light emitting device, and at least one third light control device disposed on the third light emitting device, the at least one third light control device having a shape symmetrical to a shape of the at least one first light control device.
